(19) United States
(12) Patent Application Publication
(10) Pub. No.: US 2013/0177847 A1
(43) Pub. Date: Jul. 11, 2013

(54) PHOTORESIST FOR IMPROVED LITHOGRAPHIC CONTROL

(71) Applicant: Applied Materials, Inc., Santa Clara, CA (US)

(72) Inventors: Amit Chatterjee, Cupertino, CA (US); Abhijit Basu Mallick, Palo Alto, CA (US); Nitin K. Ingle, San Jose, CA (US)

(73) Assignee: Applied Materials, Inc., Santa Clara, CA (US)

(21) Appl. No.: 13/633,252

(22) Filed: Oct. 2, 2012

Related U.S. Application Data
(60) Provisional application No. 61/569,489, filed on Dec. 12, 2011.

(51) Int. Cl. G03F 7/075; G03F 7/20

(52) U.S. Cl. CPC G03F 7/0757; G03F 7/20
USPC 430/270.1; 430/319

(57) ABSTRACT

Methods and corresponding photoresists are described for fine linewidth lithography using x-rays, e-beams, visible spectrum optical lithography, ultra-violet optical lithography or extreme ultra-violet lithography. The methods include the formation of a photoresist film including a dopant having an atomic mass greater than or equal to twenty two. The dopant may be introduced daring the formation of the photoresist. The photoresist includes the dopant to increase the absorption of radiation during lithography. The photoresist may be silicon-, germanium or carbon-based photoresists.

### CROSS-REFERENCES TO RELATED APPLICATIONS

This application claims the benefit of U.S. Prov. Pat. App. No. 61/569,489 filed Dec. 12, 2011, and titled “PHOTORESIST FOR IMPROVED LITHOGRAPHIC CONTROL,” which is incorporated herein by reference for all purposes.

### BACKGROUND OF THE INVENTION

Photolithography employs photoresists, which are photosensitive films, for transfer of negative or positive images onto a substrate, e.g., a semiconductor wafer. Subsequent to coating a substrate with a photoresist, the coated substrate is exposed to a source of activating radiation, which causes a chemical transformation in the exposed areas of the surface. The photo-resist coated substrate is then treated with a developer solution to dissolve or otherwise remove either the radiation-exposed or unexposed areas of the coated substrate, depending on the type of photoresist employed.

Lithographic techniques for creation of features having sizes of thirty nanometers or less, however, suffer from a number of shortcomings. For example, line width variations of a resist film produced by such techniques can be too large to be acceptable in view of tightening dimensional tolerances typically required in this range, e.g., tolerances of the order of the scales of the molecular components of the resist film. Such linewidth variations may be classified as line edge roughness (LER) and/or line width roughness (LWR).

Line edge roughness and line width roughness reflect linewidth fluctuations that may lead to variations in device characteristics. As critical dimensions for integrated circuits continued to shrink, linewidth fluctuations will play an increasingly significant role in critical dimensions (CD) error budget for lithography. Several suspected sources of LER and LWR in resist patterns include the reticle quality, the aerial image quality, and resist material properties.

Positive tone photoresists have typically been used for the finest geometries. Positive tone photoresists may employ an embedded photo-acid generator (PAG) within a hydrophobic polymer. Regions exposed to light (or other excitation) are weakened when a strong acid is generated from the photo-acid generator. The strong acid switches the polarity of the polymer to become soluble in aqueous base. Line edge or width roughness results, in part, from the diffusion ranges of the pockets of the photo-acid generator and the strong acid formed therefrom. Attempts have been made to control the line edge or width roughness, tor example, by further embedding a minority concentration of a base to corral the acidic reaction within organic photoresists. However, this type of technique may be unsatisfactory for small linewidths requiring advanced lithographic techniques, such as X-ray, e-beam or extreme ultra-violet (EUV) lithography

Thus, there is a need for new photoresists and deposition processes which result in improved control of line edge or width roughness for fine features. This and other needs are addressed in the present application.

### BRIEF SUMMARY OF THE INVENTION

Methods and corresponding photoresists are described for fine linewidth lithography using x-rays, e-beams, visible spectrum optical lithography, ultra-violet optical lithography or extreme ultra-violet lithography. The methods include the formation of a photoresist film including a dopant having an atomic mass greater than or equal to twenty two. The dopant may be introduced during the formation of the photoresist. The photoresist includes the dopant to increase the absorption of radiation during lithography. The photoresist may be silicon-, germanium or carbon-based photoresists.

Embodiments of die invention include photoresist layers formed on a semiconductor substrate. The photoresist layers include a dopant. The atomic number of the dopant is greater than or equal to twenty two.

Embodiments of the invention further include methods of forming a photoresist layer on a semiconductor substrate. The methods include forming a photoresist layer on the semiconductor substrate, in which the photoresist layer comprises a dopant having an atomic number greater than or equal to twenty two.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of fee present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel it is intended to refer to all such multiple similar components.

FIG. 1 is a flowchart illustrating selected steps for making a photoresist film according to embodiments of the invention.

FIG. 2 is a table of elemental dopants and their extreme UV absorption relative to hydrogen according to embodiments of the invention.

FIGS. 3A-3B are graphs of extreme UV absorption relative to hydrogen for elemental dopants according to embodiments of the invention.

FIG. 4 shows a substrate processing system according to embodiments of the invention.

FIG. 5A shows a substrate processing chamber according to embodiments of the invention.

FIG. 5B shows a showerhead of a substrate processing chamber according to embodiments of the invention.

### DETAILED DESCRIPTION OF THE INVENTION

Methods and corresponding photoresists are described for fine linewidth lithography using x-rays, e-beams, visible spectrum optical lithography, ultra-violet optical lithography or extreme ultra-violet lithography. The methods include the formation of a photoresist film including a dopant having an atomic mass greater than or equal to twenty two. The dopant may be introduced during the formation of the photoresist. The photoresist includes the dopant to increase the absorption of radiation during lithography. The photoresist may be silicon-, germanium or carbon-based photoresists.

Many current photoresists are at least somewhat translucent to higher energy photolithographic techniques results, such as extreme UV (EUV) photolithography. This can increase line edge roughness (LER) and/or line width roughness (LWR) as a result of stray radiation reflected from underlying layers and then subsequently absorbed into the photoresist layer. Multiple reflections can occur before the radiation is ultimately absorbed. The doped photoresists described herein result in photo-activity with greatly increased absorption of high-energy lithographic radiation sources. These doped photoresists enable a direct action of the incident radiation to result in transformation of the silicon polymer rather than reliance on a secondary scattering reaction in embodiments. Increasing the absorption of radiation is also desirable in order to efficiently use lithographic radiation having reduced intensity. New lithographic radiation sources having lower wavelengths are expected to offer reduced radiative intensity. The techniques presented herein involve introducing dopants to photoresists during formation and may be used for either positive or negative tone photolithographic processing sequences.

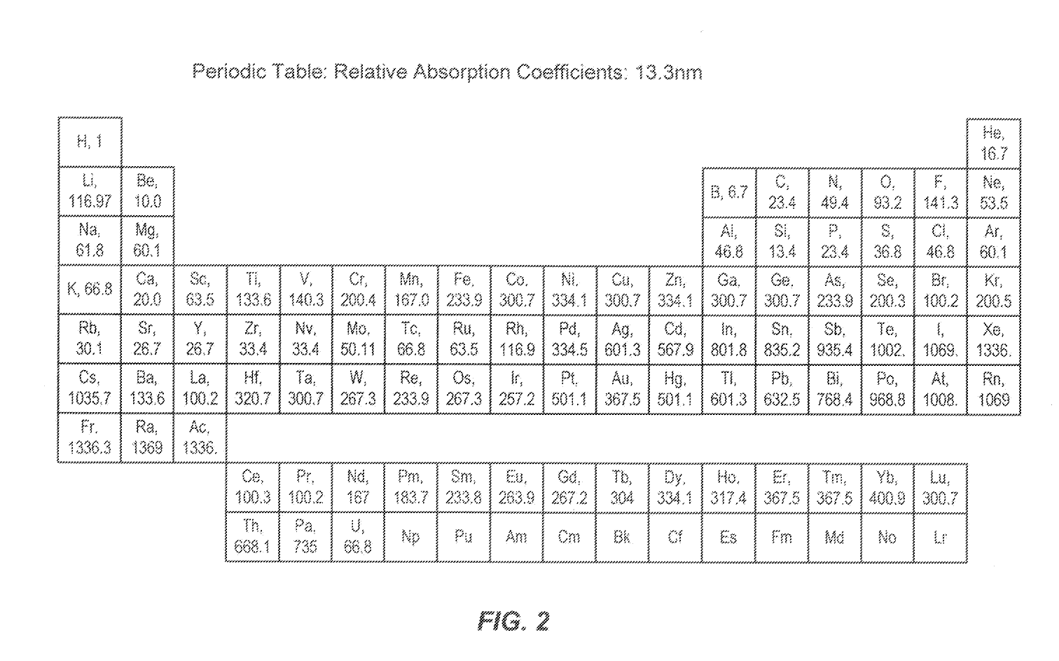

FIG. 2 is a table of elemental dopants and their extreme UV absorption relative to hydrogen according to embodiments of the invention. The dopants have been found to promote absorption of high energy lithographic radiation sources, such as EUV radiation, in silicon-based photoresists. Absorption is increased for EUV radiation at or below thirty nanometers in wavelength (e.g. 13.3 nm). The dopants may be from groups IV, V, VI and VII of the periodic table in embodiments. The absorption generally increases as the atomic number increases (right→left and then up→down) in the table of FIG. 2. One of the first elemental dopants which possess over one hundred times the absorption of hydrogen is titanium (atomic number 22). Dopants for silicon-based photoresists may have an atomic number of 22 or more, an atomic number of 45 or more or an atomic number of 80 or more in embodiments of the invention. The absorption relative to hydrogen may be greater than 100, greater than 200, greater than 400, greater than 600 or greater than 800 in disclosed embodiments. The relative absorptions given herein describe the specific absorption of EUV light having around 13.3 nm wavelength, however, the increase in absorption may also apply to x-ray lithography, ultra-violet optical lithography, visible optical lithography or e-beam lithography suitable for fine linewidth feature formation.

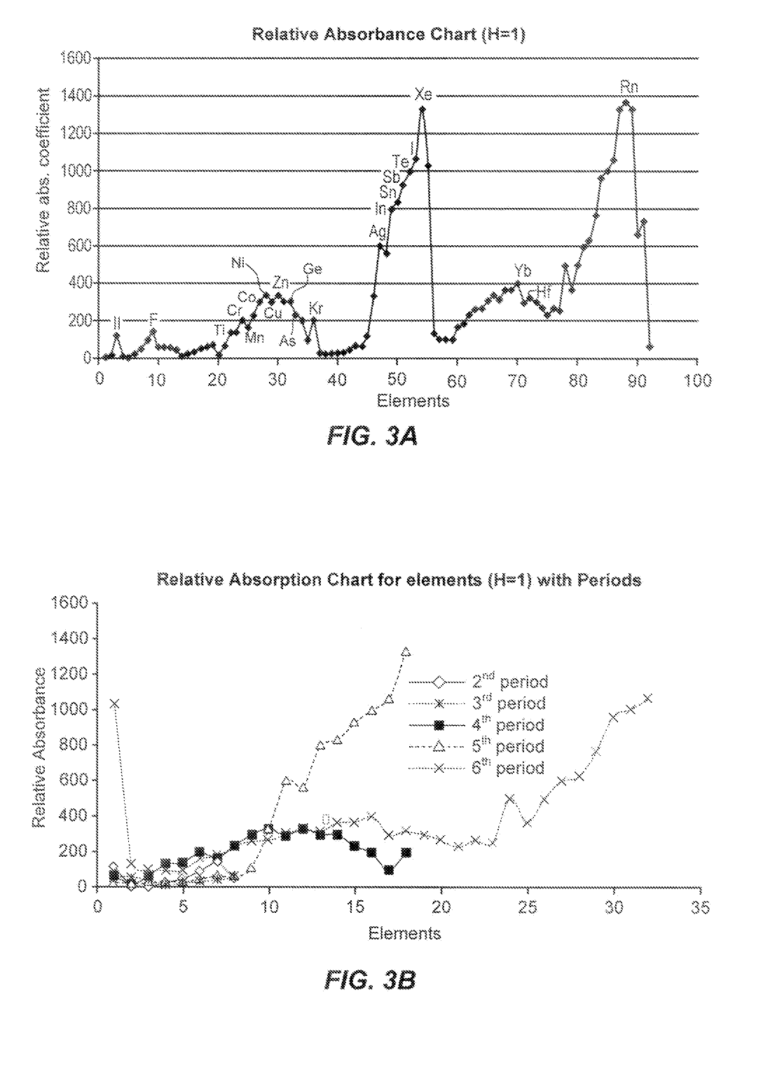

FIGS. 3A-3B are graphs which provide alternative views of the relative absorption of elemental dopants. These views show a finer structure in the dependence of relative absorption on atomic number. The increase in relative absorption is clearly distinct from a monotonically increasing dependence. The first group ox elemental dopants having relative absorption greater than one hundred includes elements having atomic number of 22 through 36. The second group of elemental dopants having relative absorption greater than one hundred includes elements having atomic number of 45 through 91. Elements of the first or second group may be used as dopants according to embodiments of the invention. Within the second group, elemental dopants having atomic number of 49 through 55 possess relative absorption greater than 800. The elemental dopant may be one of indium (In, atomic number 49), tin (Sn, 50), antimony (Sb, 51), tellurium (Te, 52), iodine (I, 53), xenon (Xe, 54) or (Cs, 55) in disclosed embodiments. Another significant peak occurs for elemental dopants having atomic number of 81 through 91. The elemental dopant may be one of thallium (Tl, 81), lead (Pb, 82), bismuth (Bi, 83), polonium (Po, 84), astatine (At 85), radon (Rn, 86), francium (Fr, 87), radium (Ra, 88), actinium (Ac, 89), thorium (Th, 90) or protactinium (Pa, 91) in disclosed embodiments. Each of these latter elemental dopants offer a relative absorption greater than 600 compared to hydrogen. As indicated previously, the relative absorption relative to hydrogen may be greater than 800 which may be used to dramatically increase absorption of photolithographic radiation. In this case the elemental dopant may be one of indium, tin, antimony, tellurium, iodine, xenon, cesium, thallium, polonium, astatine, radon, francium, radium, or actinium in disclosed embodiments. The elemental dopant may also be one of silver, cadmium, indium, tin, antimony, tellurium and iodine in order to make the material more readily available and possess a relative absorption greater than 600. The elemental dopant may also be one of indium, tin, antimony, tellurium and iodine in order to combine high availability and a relative absorption greater than 800.

### Exemplary Photoresist Formation Process

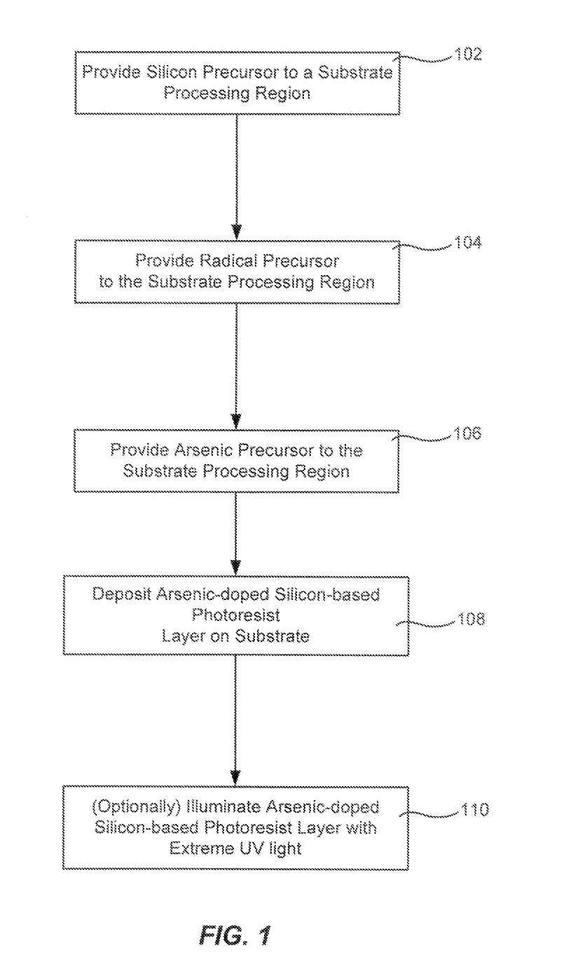

The doped photoresist films described herein may be a carbon-based photoresist (e.g. PMMA, epoxy and the like) or the doped films may be a silicon-based photoresist (an example of a silicon-based photoresist is described below). FIG. 1 is a flowchart showing selected steps in methods of making silicon-based photoresist films according to embodiments of the invention. The method includes providing a silicon-containing precursor to a substrate processing region 102. The silicon-containing precursor may be, for example, a silicon-and-nitrogen precursor, a silicon-and-hydrogen precursor, or a silicon-nitrogen-and-hydrogen containing precursor, among other classes of silicon-containing precursors. Specific examples of these precursors may include silyl-amines such as H₂N(SiH₃), HN(SiH₃)₂, and N(SiH₃)₃, among other silyl-amines. These silyl-amines may be mixed with additional gases that may act as carrier gases, reactive gases, or both. Examples of additional gases may include H₂, N₂, NH₃, He, and Ar, among other gases. Examples of silicon-containing precursors may also include silane (SiH₄) either alone or mixed with other silicon-containing gases (e.g., N(SiH₃)₃), hydrogen-containing gases (e.g., H₂), and/or nitrogen-containing gases (e.g., N₂, NH₃). Silicon-containing precursors may also include disilane, trisilane, higher-order silanes, and chlorinated silanes, alone or in combination with one another or the previously mentioned silicon-containing precursors.

A radical precursor is also provided to the substrate processing region 104. The radical precursor may contain nitrogen and may be referred to as a radical-nitrogen precursor herein. The radical-nitrogen precursor is a nitrogen-radical containing species that was generated outside the substrate processing region from a more stable nitrogen precursor. For example, a relatively stable nitrogen precursor such a NH₃ and/or hydrazine (N₂H₄) may be activated in a plasma unit outside the substrate processing region to form the radical-nitrogen precursor, which is then transported into the substrate processing region. The stable nitrogen precursor may also be a mixture comprising NH₃ & N₂, NH₃ & H₂, NH₃ & N₂ & H₂ and N₂ & H₂, in different embodiments. Hydrazine may also be used in place of or in combination with NH₃ in the mixtures with N₂ and H₂. The radical-nitrogen precursor produced may be one or more of .N, .NH, .NH₂, etc., and may also be accompanied by ionized species formed in the plasma.

Generally speaking, a radical precursor which does not include nitrogen will also allow a silicon-and-nitrogen-containing layer to be formed. A radical precursor may be a radical-nitrogen precursor if it includes nitrogen supplied with the aforementioned precursors to the remote plasma region. The radical precursor is generated in a section of the chemical vapor deposition chamber partitioned from the substrate processing region where the precursors mix and react to deposit the silicon-based photoresist layer on a deposition substrate (e.g., a semiconductor wafer or semiconductor substrate). In an embodiment where the radical precursor is a radical-nitrogen precursor, a stable nitrogen precursor is flowed into the remote plasma region and excited by a plasma. The stable nitrogen precursor (and the radical-nitrogen precursor) may also be accompanied by a carrier gas such as hydrogen (H₂), nitrogen (N₂), argon, helium, etc. A radical-nitrogen precursor formed from an input gas consisting essentially of nitrogen (N₂) (with or without additional inert carrier gases) has also been found to produce beneficial films in disclosed embodiments. The radical-nitrogen precursor may also be replaced by a radical precursor formed from an input gas consisting essentially of hydrogen (H₂) (and optionally inert carrier gases) in embodiments where the silicon-containing precursor comprises nitrogen.

A dopant precursor is also provided to the substrate processing region 106. The dopant precursor may contain any of the dopants described previously. In the exemplary process, the dopant is arsenic and the dopant precursor is arsine (ArH₃) but may be another arsenic-containing precursor. The dopant precursor may be flowed into the substrate processing region without first passing through a remote plasma region (analogous to the silicon-containing precursor) in embodiments of the invention. In the substrate processing region, the silicon-containing precursor, the dopant precursor and the radical-nitrogen precursor mix and react to deposit the silicon-based photoresist film on the deposition substrate 108.

The silicon-based photoresist film may then be exposed to EUV light having a wavelength of about 13.3 nm 110. The EUV light may be filtered by a mask to transfer a latent image onto the photoresist film. The presence of the dopants described herein increases the absorption of a variety of photolithography radiation including EUV light having wavelength near 13.3 nm.

The photoresist may be flowable during deposition. A flowable deposition serves to locally planarize the silicon-based photoresist which enhances the clarity of the latent image aligning the surface of the photoresist within the depth-of-field of the masked EUV light. Flowability may be due to a variety of properties which result from mixing a radical-nitrogen precursors with the silicon-containing precursor. These properties may include a significant hydrogen component in the deposited film and/or the presence of short chained polysilazane polymers. These poly-silazane chains grow and network to form more dense dielectric material during and after the formation of the film. For example the deposited film may have a silazane-type, Si—NH—Si backbone (i.e., a Si—N—H film). These polysilazane networks are also beneficial for the lithographic activity of the photoresist film since the networks can be weakened or strengthened as desired for positive or negative tone lithographic processes. The photoresist may be referred to as a positive tone photoresist or a negative tone photoresist herein.

The exemplary deposition process describes chemical vapor deposition of the photoresist film. In general the photoresist may be carbon-based or germanium based in addition to the silicon-based example described herein. The dopants described herein can still increase absorption of e-beam or optical radiation to improve photolithography. In embodiments of the invention, the silicon, carbon or germanium-based photoresist film may be formed by means other than chemical vapor deposition, for example, by forming a “spin-on glass” (SOG) or “spin-on dielectric” (SOD) in disclosed embodiments. Spin-on techniques may involve delivering a liquid precursor to a rotating surface of the substrate. The liquid precursor may be a liquid silicon-containing precursor, a liquid germanium-containing precursor or a liquid carbon-containing precursor in disclosed embodiments. The dopant is provided within the liquid precursors.

### Exemplary Silicon Oxide Deposition System

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PBCVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

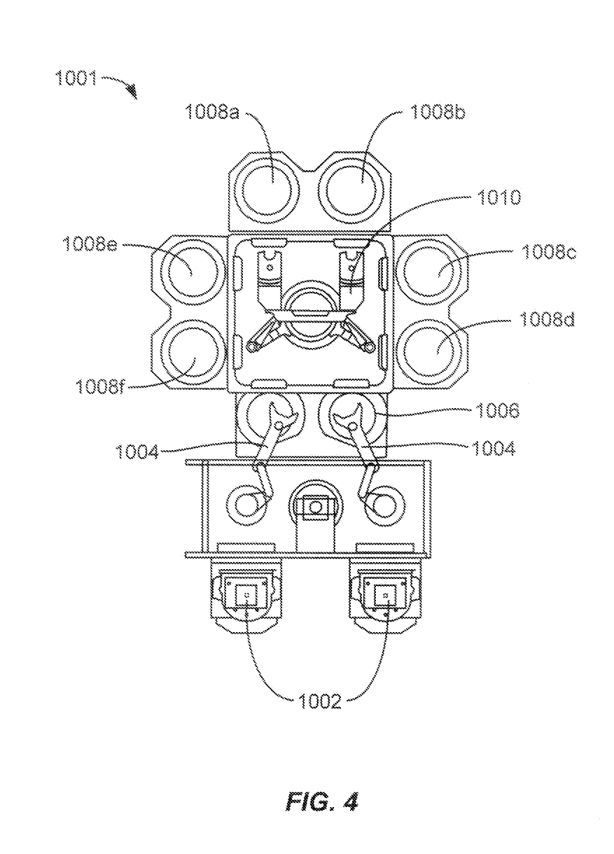

Embodiments of the deposition systems may be incorporated into larger fabrication systems for producing integrated circuit chips. FIG. 4 shows one such system 1001 of deposition, baking and curing chambers according to disclosed embodiments. In the figure, a pair of FOUPs (front opening unified pods) 1002 supply substrate substrates (e.g., 300 mm diameter wafers) that are received by robotic arms 1004 and placed into a low pressure holding area 1006 before being placed into one of the wafer processing chambers 1008a-f. A second robotic arm 1010 may be used to transport the substrate wafers from the holding area 1006 to the processing chambers 1008a-f and back.

The processing chambers 1008a-f may include one or more system components for depositing, annealing, curing and/or etching a flowable dielectric film on the substrate wafer. In one configuration, two pairs of the processing chamber (e.g., 1008c-d and 1008e-f) may be used to deposit the flowable dielectric material on the substrate, and the third pair of processing chambers (e.g., 1008a-b) may be used to anneal the deposited dieleletric. In another configuration, the same two pairs of processing chambers (e.g., 1008c-d and 1008e-f) may be configured to both deposit and anneal a flowable dielectric film on the substrate, while the third pair of chambers (e.g., 1008a-b) may be used for UV or E-beam curing of the deposited film. In still another configuration, all three pairs of chambers (e.g., 1008a-f) may be configured to deposit and cure a flowahle dielectric film on the substrate. In yet another configuration, two pairs of processing chambers (e.g., 1008c-d and 1008e-f) may be used for both deposition and UV or E-beam curing of the flowable dielectric, while a third pair of processing chambers (e.g. 1008a-b) may be used for annealing the dielectric film. Any one or more of the processes described may be carried out on chamber(s) separated from the fabrication system shown in different embodiments.

In addition, one or more of the process chambers 1008a-f may be configured as a wet treatment chamber. These process chambers include heating the flowable dielectric film in an atmosphere that includes moisture. Thus, embodiments of system 1001 may include wet treatment chambers 1008a-b and anneal processing chambers 1008c-d to perform both wet and dry anneals on the deposited dielectric film.

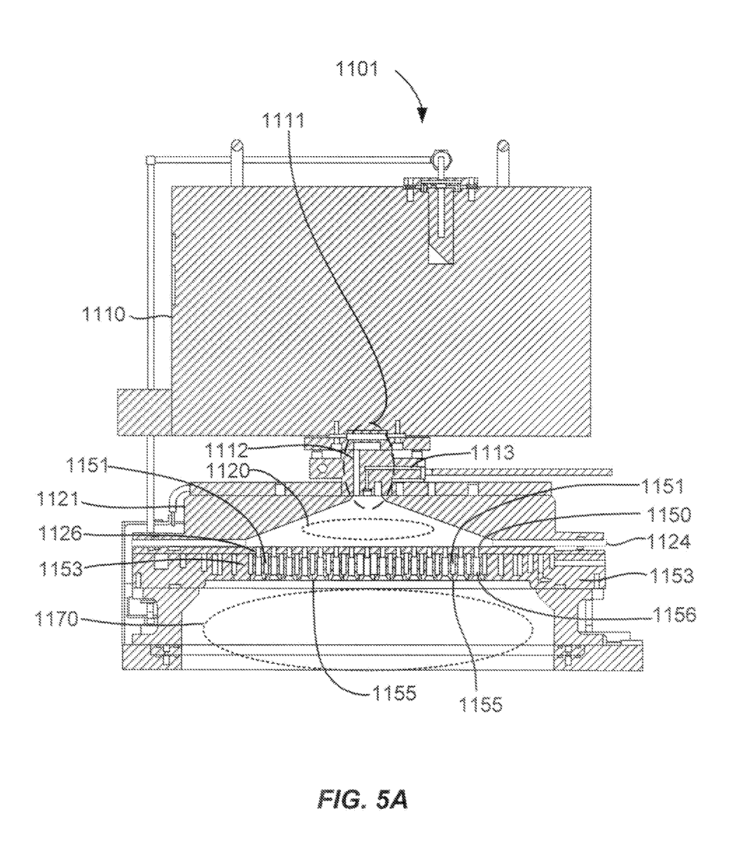

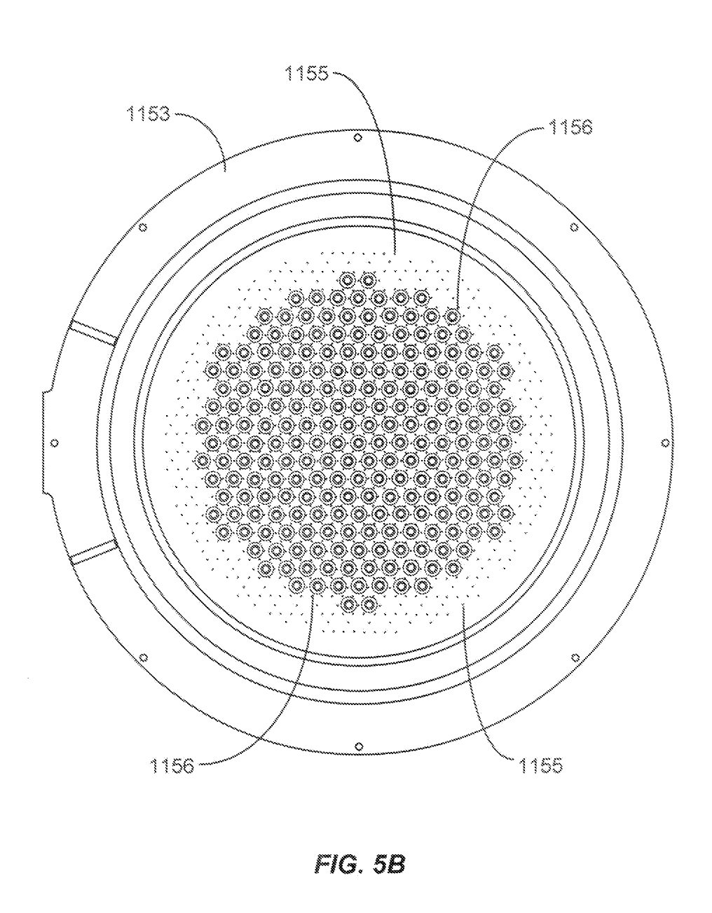

FIG. 5A is a substrate processing chamber 1101 according to disclosed embodiments. A remote plasma system (RPS) 1110 may process a gas which then travels through a gas inlet assembly 1111. Two distinct gas supply channels arc visible within the gas inlet assembly 1111. A first channel 1112 carries a gas that passes through the remote plasma system RPS 1110, while a second channel 1113 bypasses the RPS 1110. First channel 1112 may be used for the process gas and second channel 1113 may be used for a treatment gas In disclosed embodiments. The lid (or conductive top portion) 1121 and a perforated partition (showerhead 1153) are shown with an insulating ring 524 in between, which allows an AC potential to be applied to the lid 1121 relative to showerhead 1153. The process gas travels through first channel 1112 into chamber plasma region 1120 and may be excited by a plasma in chamber plasma region 1120 alone or in combination with RPS 1110. The combination of chamber plasma region 1120 and/or RPS 1110 may be referred to as a remote plasma system herein. The showerhead 1153 separates chamber plasma region 1120 from a substrate processing region 1170 beneath showerhead 1153. Showerhead 1153 allows a plasma present In chamber plasma region 1120 to avoid directly exciting gases in substrate processing region 1170, while still allowing excited species to travel from chamber plasma region 1120 into substrate processing region 1170.

Showerhead 1153 is positioned between chamber plasma region 1120 and substrate processing region 1170 and allows plasma effluents (excited derivatives of precursors or other gases) created within chamber plasma region 1120 to pass through a plurality of through-holes 1156 that traverse the thickness of the plate. The showerhead 1153 also has one or more hollow volumes 1151 which can be filled with a precursor in the form of a vapor or gas (such as a silicon-containing precursor) and pass through small holes 1155 into substrate processing region 1170 but not directly into chamber plasma region 1120. Showerhead 1153 is thicker than the length of the smallest diameter 1150 of the through-holes 1156 in this disclosed embodiment. In order to maintain a significant concentration of excited species penetrating from chamber plasma region 1120 to substrate processing region 1170, the length 526 of the smallest diameter 1150 of the through-holes may be restricted by forming larger diameter portions of through-holes 1156 part way through the showerhead 1153. The length of the smallest diameter 1150 of the through-holes 1156 may be the same order of magnitude as the smallest diameter of the through-holes 1156 or less in disclosed embodiments.

In the embodiment shown, showerhead 1153 may distribute (via through-holes 1156) process gases which contain oxygen, hydrogen and/or nitrogen and/or plasma effluents of such process gases upon excitation by a plasma in chamber plasma region 1120. In embodiments, the process gas introduced into the EPS 1110 and/or chamber plasma region 1120 through first channel 1112 may contain one or more of oxygen (O₂), ozone (O₃), N₂O, NO, NO₂, NH₃, NₓH_{y} including N₂H₄, share, disilane, TSA and DSA. The process gas may also include a carrier gas such as helium, argon, nitrogen (N₂), etc. The second channel 1113 may also deliver a process gas and/or a carrier gas, and/or a film-curing gas used to remove an unwanted, component from the growing or as-deposited film. Plasma effluents may include ionized or neutral derivatives of the process gas and may also be referred to herein as a radical-oxygen precursor and/or a radical-nitrogen precursor referring to the atomic constituents of the process gas introduced.

In embodiments, the number of through-holes 1156 may be between about 60 and about 2000. Through-holes 1156 may have a variety of shapes but are most easily made round. The smallest diameter 1150 of through-holes 1156 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 1155 used to introduce a gas into substrate processing region 1170 may be between about 100 and about 5000 or between about 500 and about 2000 in different embodiments. The diameter of the small holes 1155 may be between about 0.1 mm and about 2 mm.

FIG. 5B is a bottom view of a showerhead 1153 for use with a processing chamber according to disclosed embodiments. Showerhead 1153 corresponds with the showerhead shown in FIG. 5A. Through-holes 1156 are depicted with a larger inner-diameter (ID) on the bottom of showerhead 1153 and a smaller ID at the top. Small holes 1155 are distributed substantially evenly over the surface of the showerhead, even amongst the through-holes 1156 which helps to provide more even mixing than other embodiments described herein.

An exemplary film is created on a substrate supported by a pedestal (not shown) within substrate processing region 1170 when plasma effluents arriving through through-holes 1156 in showerhead 1153 combine with a silicon-containing precursor arriving through the small holes 1155 originating from hollow volumes 1151. Though substrate processing region 1170 may be equipped to support a plasma for other processes such as curing, no plasma is present during the growth of the exemplary film.

A plasma may be ignited either in chamber plasma region 1120 above showerhead 1153 or substrate processing region 1170 below showerhead 1153. A plasma is present in chamber plasma region 1120 to produce the radical-nitrogen precursor from an inflow of a nitrogen-and-hydrogen-containing gas. An AC voltage typically in the radio frequency (RF) range is applied between the conductive top portion 1121 of the processing chamber and showerhead 1153 to ignite a plasma in chamber plasma region 1120 during deposition. An RF power supply generates a high RF frequency of 13.56 MHz but may also generate other frequencies alone or in combination with the 13.56 MHz frequency.

The top plasma may be left at low or no power when the bottom plasma in the substrate processing region 1170 is turned on to either cure a film or clean the interior surfaces bordering substrate processing region 1170. A plasma in substrate processing region 1170 is ignited by applying an AC voltage between showerhead 1153 and the pedestal or bottom of the chamber. A cleaning gas may be introduced into substrate processing region 1170 while the plasma is present.

The pedestal may have a heat exchange channel through which a heat exchange fluid flows to control the temperature of the substrate. This configuration allows the substrate temperature to be cooled or heated to maintain relatively low temperatures (from 0° C. through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interlace boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the CVD machine. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack on a substrate or a process for cleaning a chamber can be implemented using a computer program product that is executed by the system controller. The computer program code can be written in any conventional computer readable programming language: for example, 68000 assembly language, C, C++, Pascal, Fortran, or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interlace between a user and the controller is via a flat-panel touch-sensitive monitor. In the preferred embodiment two monitors are used, one mounted in the clean room wall for the operators and the other behind the wall for the service technicians. The two monitors may simultaneously display the same information, in winch case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

The chamber plasma region or a region In an RPS may be referred to as a remote plasma region. In embodiments, the radical-nitrogen precursor is created in the remote plasma region and travels into the substrate processing region where the carbon-free silicon-containing precursor is excited by the radical-nitrogen precursor. In embodiments, the carbon-tree silicon-containing precursor is excited only by the radical-nitrogen precursor. Plasma power may essentially be applied only to the remote plasma region, in embodiments, to ensure that the radical-nitrogen precursor provides the dominant excitation to the carbon-free silicon-containing precursor.

In embodiments employing a chamber plasma region, the excited plasma effluents are generated in a section of the substrate processing region partitioned from a deposition region. The deposition region, also known herein as the substrate processing region, is where the plasma effluents mix and react with the carbon-free silicon-containing precursor to deposit the silicon-and-nitrogen layer on a deposition substrate (e.g., a semiconductor wafer). The excited plasma effluents are also accompanied by an inert gases (in the exemplary ease, argon). The carbon-free silicon-containing precursor does not pass through a plasma before entering the substrate plasma region, in embodiments. The substrate processing region may be described herein as “plasma-free” during the growth of the silicon-and-nitrogen-containing layer. “Plasma-free” does not necessarily mean the region is devoid of plasma. Ionized species and free electrons created within the plasma region do travel through pores (apertures) in the partition (showerhead) but the carbon-free silicon-containing precursor is not substantially excited by the plasma power applied to the plasma region. The borders of the plasma in the chamber plasma region are hard to define and may encroach upon the substrate processing region through the apertures in the showerhead. In the case of an inductively-coupled plasma, a small amount of ionization may be effected within the substrate processing region directly. Furthermore, a low intensity plasma may be created in the substrate processing region without eliminating desirable features of the forming film. All causes for a plasma having much lower intensity ion density than the chamber plasma region (or a remote plasma region, for that matter) during the creation of the excited plasma effluents do not deviate from the scope of “plasma-free” as used herein.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. A layer of “silicon oxide” is used as a shorthand for and interchangeably with a silicon-and-oxygen-containing material. As such, silicon oxide may include concentrations of other elemental constituents such as nitrogen, hydrogen, carbon and the like. In some embodiments, silicon oxide consists essentially of silicon and oxygen. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas may be a combination of two or more gases. A “radical precursor” is used to describe plasma effluents (a gas in an excited state which is exiting a plasma) which participate in a reaction to either remove material from or deposit material on a surface. A “radical-nitrogen precursor” is a radical precursor which contains nitrogen. The phrase “inert gas” refers to any gas which does not form chemical bonds when incorporated into a film. Exemplary inert gases include noble gases but may include other gases so long as no chemical bonds are formed when (typically) trace amounts are trapped in a film.

The term “trench” is used throughout with no implication that the etched geometry has a large horizontal aspect ratio. Viewed from above the surface, trenches may appear circular, oval, polygonal, rectangular, or a variety of other shapes. The term “via” is used to refer to a low aspect ratio trench which may or may not be filled with metal to form a vertical electrical connection. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursor and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of forming a photoresist layer on a semiconductor substrate, the method comprising:
forming a photoresist layer on the semiconductor substrate, wherein the photoresist layer comprises a dopant having an atomic number greater than or equal to twenty two.

2. The method of claim 1 wherein the photoresist layer comprises a carbon-based photoresist, a germanium-based photoresist or a silicon-based photoresist.

3. The method of claim 1 wherein the photoresist layer comprises poly-silazane chains.

4. The method of claim 1 wherein forming the photoresist layer on the semiconductor substrate comprises delivering a liquid precursor to the surface of the semiconductor substrate, wherein the dopant is provided within, the liquid precursor.

5. The method of claim 1 wherein forming the photoresist layer on the semiconductor substrate comprises forming the photoresist layer by chemical vapor deposition, the dopant providing precursors to a substrate processing region to form the photoresist layer on the semiconductor substrate wherein the photoresist layer comprises the dopant.

6. The method of claim 1 wherein the dopant is one of silver, cadmium, indium, tin, antimony, tellurium and iodine.

7. The method of claim 1 further comprising forming an EUV image on the photoresist to expose the photoresist.

8. The method of claim 1 wherein the precursors comprise a radical precursor formed in a remote plasma and a silicon-containing precursor which does not pass through a remote plasma before entering the substrate processing region.

9. The method of claim 8 wherein the precursors further comprise a dopant precursor comprising the dopant.

10. The method of claim 8 wherein the radical precursor is formed by flowing ammonia into the remote plasma, wherein the radical precursor comprises plasma effluents formed in the remote plasma and flowed into the substrate processing region.

11. The method of claim 8 wherein the silicon-containing precursor comprises a silyl-amine.

12. The method of claim 11 wherein the silyl-amine is N(SiH₃)₃.

13. A photoresist layer formed on a semiconductor substrate, the photoresist layer comprising a dopant, wherein the atomic number of the dopant is greater than or equal to twenty two.

14. The method of claim 13 wherein the photoresist layer comprises a carbon-based photoresist, a germanium-based photoresist or a silicon-based photoresist.

15. The photoresist layer of claim 13 wherein the photoresist layer comprises poly-silazane chains.

16. The photoresist layer of claim 13 wherein the dopant has an atomic number greater than or equal to forty five.

17. The photoresist layer of claim 13 wherein the dopant is one of silver, cadmium, indium, tin, antimony, tellurium and iodine.

18. The photoresist layer of claim 13 wherein the photoresist layer is a negative tone photoresist.

19. The photoresist layer of claim 13 wherein the photoresist layer is a positive tone photoresist.

20. The photoresist layer of claim 13 wherein the dopant has a relative absorption greater than or about 600 compared to hydrogen for EUV light.
